(19) United States
(12) Patent Application Publication
(10) Pub. No.: US 2026/0066775 A1
(43) Pub. Date: Mar. 5, 2026

(54) POWER CONVERTER OVERPOWER PROTECTION CIRCUIT

(71) Applicant: TEXAS INSTRUMENTS INCORPORATED, Dallas, TX (US)

(72) Inventors: Bing Lu, Bedford, NH (US); Akhila Gundavarapu, Bangalore (IN); Prathamesh Pilankar, Mumbai (IN); Michael Lueders, Freising (DE); Suvadip Banerjee, Bangalore (IN); Ramkumar Sivakumar, Bangalore (IN)

(21) Appl. No.: 19/007,636

(22) Filed: Jan. 2, 2025

Related U.S. Application Data
(60) Provisional application No. 63/685,453, filed on Aug. 21, 2024.

(51) Int. Cl. H02M 1/34; H02M 1/00; H02M 1/08; H02M 1/092; H02M 1/44; H02M 7/21; H03K 19/003

(52) U.S. Cl. CPC H02M 1/348; H02M 1/0009; H02M 1/083; H02M 1/092; H02M 1/44; H02M 7/21; H03K 19/00315

(57) ABSTRACT

Described embodiments include a protection circuit having a voltage attenuator circuit with an input coupled to a switch terminal. A filter circuit has a filter input coupled to the output of the attenuator. A first transistor has a first current terminal coupled to a power supply terminal, and a first control terminal coupled to the filter output. A second transistor, which is matched to the first transistor, has a third current terminal coupled to the first current terminal, a second control terminal coupled to the first control terminal, and a fourth current terminal coupled to a first voltage sense terminal. A buffer circuit has a buffer input coupled to the attenuator output. A S/H circuit has a sample input coupled to the buffer output, and a sample output providing a minimum ringing voltage of a signal from the switch terminal.

### CROSS-REFERENCE TO RELATED APPLICATION

This application claims priority to U.S. Provisional Patent Application No. 63/685,453 filed Aug. 21, 2024, which is incorporated herein by reference in its entirety.

### BACKGROUND

This description relates to power converters, such as AC-DC power converters having a regulated quasi-resonant (QR) flyback converter on the primary side of the transformer. A QR flyback converter is a direct conduction mode (DCM) flyback converter having valley switching turn-on. A QR flyback converter is sometimes used in switched-mode power supply (SMPS) applications such as chargers, adapters, and auxiliary supplies.

A typical QR flyback converter usually has two resonant oscillations occur per switching cycle in the waveform of the voltage across the power switch. A higher frequency oscillation typically occurs during the initial turn-off of the switch due to leakage inductance at the switching terminal resonating with the parasitic capacitance on the switching terminal. A second oscillation can occur when the energy in the transformer secondary winding discharges to zero.

Due to this resonant oscillation, the voltage across the switch will hit a minimum valley point. The voltage at the minimum valley point will depend on the flyback reflected voltage. In a QR flyback converter, the flyback controller provides commands to the switch to turn on when the voltage across the switch is at the minimum valley point.

### SUMMARY

In a first example, a protection circuit includes a voltage attenuator circuit having an attenuator input and an attenuator output. The attenuator input is coupled to a switch terminal. A filter circuit has a filter input and a filter output, wherein the filter input is coupled to the attenuator output. A first transistor has first and second current terminals and a first control terminal. The first current terminal is coupled to a power supply terminal, and the first control terminal is coupled to the filter output.

A second transistor has third and fourth current terminals and a second control terminal. The third current terminal is coupled to the first current terminal. The second control terminal is coupled to the first control terminal, and the fourth current terminal is coupled to a first voltage sense terminal. The second transistor is matched to the first transistor. A resistor is coupled between the second current terminal and a reference voltage terminal. A buffer circuit has a buffer input and a buffer output. The buffer input is coupled to the attenuator output.

A sample-and-hold (S/H) circuit has a sample input, a sample control terminal and a sample output. The sample input is coupled to the buffer output, and the sample output is coupled to a voltage sense terminal. The S/H circuit is configured to provide at the sample output a minimum ringing voltage of a signal from the switch terminal.

In a second example, a system includes a rectifier circuit having a rectifier input and a rectifier output. The rectifier input is coupled to an AC power input. A transformer has a transformer primary and a transformer secondary. The transformer primary is coupled to the rectifier output, and the transformer secondary is coupled to an output voltage terminal.

A voltage attenuator circuit has an attenuator input and an attenuator output. The attenuator input is coupled to a switch terminal. A filter circuit has a filter input and a filter output. The filter input is coupled to the attenuator output. A first transistor has first and second current terminals and a first control terminal. The first current terminal is coupled to a power supply terminal, and the first control terminal is coupled to the filter output.

A second transistor has third and fourth current terminals and a second control terminal. The third current terminal is coupled to the first current terminal. The second control terminal is coupled to the first control terminal, and the fourth current terminal is coupled to a first voltage sense terminal. The second transistor is matched to the first transistor. A resistor is coupled between the second current terminal and a reference voltage terminal.

A buffer circuit has a buffer input and a buffer output. The buffer input is coupled to the attenuator output. A sample-and-hold (S/H) circuit has a sample input, a sample control terminal and a sample output. The sample input is coupled to the buffer output. The sample output is coupled to a second voltage sense terminal. The S/H circuit is configured to provide at the sample output a minimum ringing voltage of a signal from the switch terminal.

### BRIEF DESCRIPTION OF THE DRAWINGS

FIG. 1 shows a schematic diagram for an example QR flyback converter.

FIG. 2 shows a plot of switch terminal voltage versus time for an example QR flyback converter.

FIG. 3 shows a schematic diagram for an example input voltage sensing circuit for a QR flyback converter without the use of a transformer auxiliary winding.

FIG. 4 shows a schematic diagram for an example plateau voltage sensing circuit for a QR flyback converter without the use of a transformer auxiliary winding.

FIG. 5 shows a schematic diagram for an example QR flyback converter without the use of a transformer auxiliary winding.

FIG. 6 shows a schematic diagram for an example current sense circuit for use in a QR flyback converter.

### DETAILED DESCRIPTION

In this description, the same reference numbers depict same or similar (by function and/or structure) features. The drawings are not necessarily drawn to scale.

In a typical quasi-resonant (QR) flyback converter, two resonant oscillations occur in the voltage signal across the power switch during each switching cycle. A first higher frequency oscillation typically occurs during the initial turn-off of the switch due to transformer leakage inductance resonating with the capacitance at the switching terminal. A second lower frequency oscillation can occur when the energy in the transformer secondary winding discharges to near zero.

During this resonant oscillation, the voltage across the switch reaches a minimum valley voltage. The voltage level at the minimum valley point is dependent upon the flyback reflected voltage. In a QR flyback circuit, the controller provides commands to cause the power switch to turn on at the minimum valley voltage.

A typical QR flyback controller uses an auxiliary transformer winding to detect the minimum valley voltage point. In response to the auxiliary winding voltage going below a certain threshold voltage during the off-time of the power switch, the controller commands the power switch to be turned on. This is known as zero current detection (ZCD) because the turning on of the power switch is triggered by the current flowing through the transformer secondary dropping to near zero. In many cases, the power switch is a field effect transistor (FET).

One possible benefit of using a QR flyback converter circuit includes having lower turn-on losses because the power switch is turning on at the lowest voltage. A second possible benefit of using a QR flyback converter circuit includes having less conducted EMI because the switching frequency is usually modulated, which spreads the noise frequency spectrum over a wider frequency band.

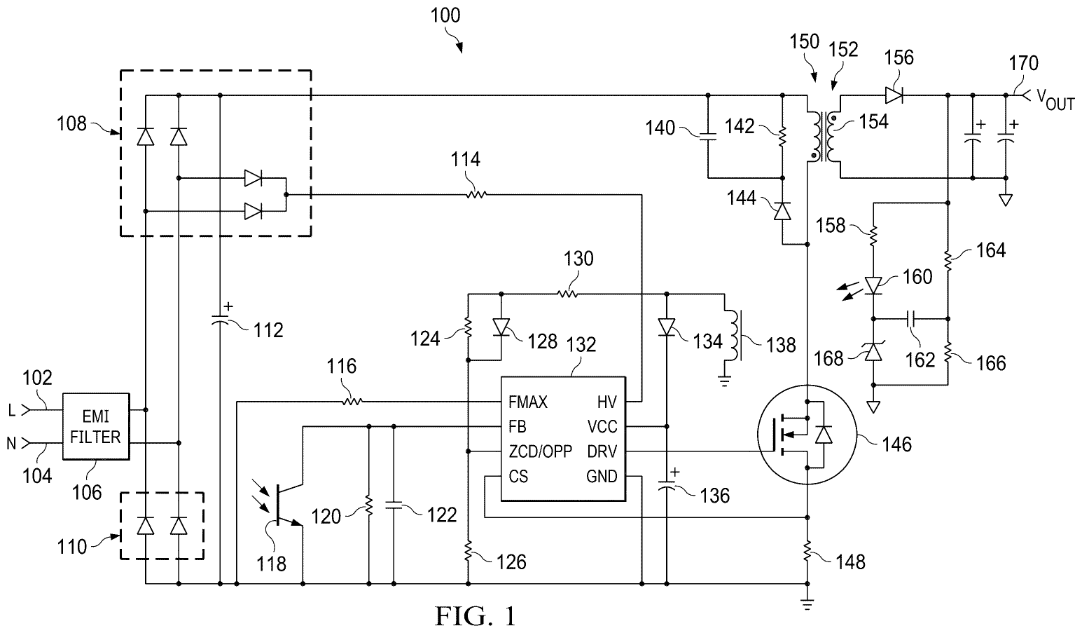

FIG. 1 shows a schematic diagram for an example QR flyback converter 100. QR flyback converter 100 receives an AC power input at input terminals 102 and 104. An EMI filter 106 has an input coupled to input terminals 102 and 104, and has an output. The output of EMI filter 106 is coupled to the input of full-wave rectifier circuit 108. Startup protection circuit 110 is coupled between the output of EMI filter 106 and a ground terminal. Capacitor 112 is coupled between a first output of full-wave rectifier circuit 108 and the ground terminal.

Transformer 154 has a primary 150, a secondary 152, and an auxiliary winding 138. The first output of full-wave rectifier circuit 108 is coupled to a first terminal of the transformer primary 150. Resistor 142 and diode 144 are coupled in series between the first terminal of the transformer primary 150 and a second terminal of the transformer primary 150. Capacitor 140 is coupled in parallel with resistor 142. FET 146 has a drain coupled to the second terminal of the transformer primary 150 and to the anode of diode 144. Resistor 148 is coupled between a source of FET 146 and the ground terminal.

The secondary 152 of transformer 154 has first and second terminals. Diode 156 has an anode coupled to the first terminal of the transformer secondary 152. A cathode of diode 156 is coupled to an output voltage terminal V_{OUT} 170. Resistor 164 and resistor 166 are connected in series between the output voltage terminal V_{OUT} 170 and the ground terminal. Resistor 158, diode 160, and zener diode 168 are connected in series between the output voltage terminal V_{OUT} 170 and the ground terminal. Capacitor 162 is coupled between the cathode of diode 160 and the cathode of zener diode 168.

In at least one case, flyback controller circuit 132 is an 8-terminal integrated circuit (IC). Flyback controller circuit 132 has a maximum frequency terminal FMAX, a feedback terminal FB, a zero-crossing detection/overpower protection terminal ZCD/OPP, a limit comparator terminal CS, a GND terminal that is coupled to the ground terminal, a drive terminal DRV that is coupled to the control terminal of FET 146, a supply terminal VCC, and a high voltage startup terminal HV.

The FMAX terminal is coupled to ground through transistor 116. Transistor 118 is coupled between the FB terminal and the ground terminal. Resistor 120 and capacitor 122 are coupled in parallel between the FB terminal and the ground terminal. The ZCD/OPP terminal is coupled to the ground terminal through resistor 126. The CS terminal is coupled to the source of FET 146. Capacitor 136 is coupled between the VCC terminal and the ground terminal. Resistor 124 is coupled in parallel with diode 128. A first terminal of resistor 130 is coupled to the anode of diode 128. Transformer auxiliary winding 138 is coupled between a second terminal of resistor 130 and the ground terminal.

FET 146 is controlled from the transformer primary 150. The output voltage V_{OUT} 170 is controlled from the transformer secondary 152. The transformer auxiliary winding 138 provides a supply to the flyback controller circuit 132. The transformer auxiliary winding 138 is a separate winding on the secondary side of transformer 154, and has the same polarity as the transformer secondary 152. The output voltage V_{OUT} 170 is the only regulated voltage in QR flyback converter 100. The voltage from the transformer auxiliary winding 138 is not regulated, but instead is an open loop output voltage from the transformer.

The transformer auxiliary winding 138 typically gives information about the input voltage being supplied to input terminals 102 and 104, and the output voltage V_{OUT} 170. This information is provided to the ZCD/OPP terminal, and the flyback controller circuit 132 processes that information to determine how to control the power switch. So, the overpower protection and sensing of the input voltage and output voltage is done by the flyback controller circuit 132 using the transformer auxiliary winding 138.

In many cases, feed forward information of the input voltage is used by flyback controller circuit 132 to provide overpower protection. Output power information is usually not directly available to the flyback controller circuit, but instead is obtained from the output voltage feedback information provided to the FB terminal of flyback controller 132.

If a constant voltage is provided to the FB terminal of flyback controller 132, or if only the voltage information of the FB terminal of flyback controller 132 is known, proper overpower protection across the input terminals 102 and 104 cannot be provided due to its inaccuracy. This inaccuracy can occur because the voltage at the FB terminal of flyback controller 132 may be different for different input voltages at the same power level. The input voltage feed forward information must also be provided to flyback controller 132 in order to provide accurate overpower protection. To meet this need, in many cases, the input voltage feed forward information and the and the switching duty cycle information are provided from the auxiliary winding.

The input power P_{IN} in a flyback converter can be calculated using equation (1):

$${P}_{IN} = ( {I}_{PK} * {V}_{IN} * D ) / 2 \qquad ( 1 )$$

where I_{PK} is the peak input current, V_{IN} is the input voltage, and D is the duty cycle. If the input power exceeds a threshold power value, the overpower protection circuit senses this and turns off the circuit to prevent damage. To provide overpower protection, the input voltage, duty cycle, and peak input current need to be determined.

The information for the input voltage, duty cycle, and peak input current can be obtained using information from the auxiliary winding. The input voltage information can be obtained directly by sensing the auxiliary winding information. The current information can be obtained by sensing or measuring the voltage across resistor 148, which has the same amount of current flowing through it as the current through FET 146.

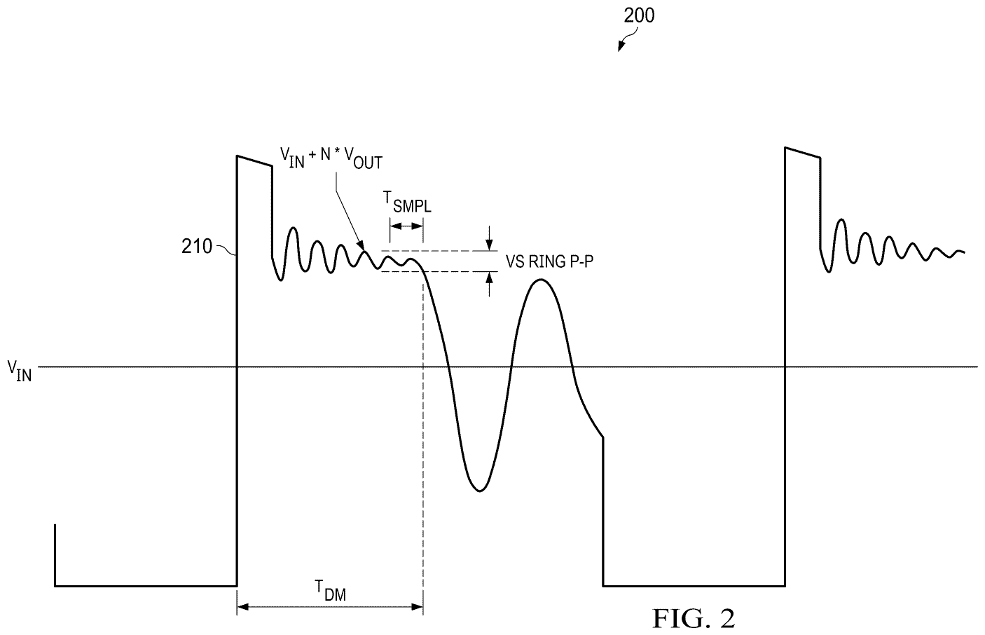

FIG. 2 shows a plot of switch terminal voltage versus time 200 for an example QR flyback converter. The switch terminal for QR flyback converter is the same terminal as the drain of FET 146. Curve 210 represents the voltage at the switch terminal, or at the drain of FET 146. The voltage at the switch terminal 210 V_{S} is centered at the voltage of V_{IN}. When FET 146 turns on, the voltage at the drain of FET 146 is equal to R_{ON}*I, where R_{ON} is the on-resistance of FET 146, and I is the current flowing through FET 146. When FET 146 is turned off, a voltage ringing occurs on the switch terminal voltage V_{S} 210. As the voltage ringing settles out, the voltage at the switch terminal 210 V_{S} settles to a plateau voltage that is equal to V_{IN}+N*V_{OUT}, where N is the turns ratio between the primary 150 and the secondary 152 of transformer 154. The plateau voltage can be sensed by sampling the switch terminal voltage V_{S} 210 during the period T_{SMPL}.

The gate drive signal from the DRV terminal of flyback controller 132, which is provided to the gate of FET 146, goes high to turn on FET 146. In at least one case, the gate drive signal is a pulse-width-modulated (PWM) signal. When FET 146 turns on, the drain-to-source voltage (V_{DS}) of FET 146 goes low. When the voltage at the switch terminal goes to near-zero, the entire voltage V_{IN} is applied across the transformer 154, and the current slowly increases.

If the current rises to a particular threshold value, a current sense circuit in flyback controller 132 determines that QR flyback converter 100 should be shut down, and the gate drive signal is brought low. Now, FET 146 is turned off and transformer 154 no longer has the voltage V_{IN} across it. So, the voltage at the switch terminal will increase to a particular value. FET 146 turns on and dumps the energy that is stored in transformer 154 into the secondary 152 of transformer 154.

When the primary is turned off, energy transfers from the transformer primary 150 into the transformer secondary 152. The voltage across the transformer secondary 152 is equal to the voltage at the output voltage terminal V_{OUT} 170. The voltage at the switch terminal V_{S} is equal to V_{IN}+N*V_{OUT}. The magnetizing current in transformer 154 decreases because the transformer is discharging into the output voltage terminal V_{OUT} 170, so the inductor current decreases.

There is parasitic capacitance at the switch terminal, which in combination with the inductance of transformer 154 causes an L-C oscillation at the switch terminal as the current drops to near-zero. After the current goes to near-zero, the voltage at the switch terminal begins to oscillate at the L-C frequency determined by the product of the inductance of the transformer auxiliary winding 138 and the parasitic capacitance at the switch terminal SW.

FET 146 is then turned on at the valley, or lowest voltage point, of the ringing voltage and when the current is at zero. FET 146 is controlled to provide near-zero voltage switching and zero current switching, which reduces switching losses. The zero-crossing detector circuit in flyback controller 132 is configured to detect the minimum voltage point of the ringing voltage waveform. The input voltage V_{IN} is equal to the average of the switch terminal voltage because there cannot be any average DC voltage across an inductor. So, the input voltage information can be obtained by averaging the voltage at the switch terminal. The plateau value of the ringing voltage is equal to V_{IN}+N*V_{OUT}, so the plateau voltage can be determined by sensing the output voltage V_{OUT} and the input voltage V_{IN} and knowing the transformer turns ratio N.

Eliminating the need for a transformer auxiliary winding in a QR flyback converter can reduce the total cost of the converter and reduce its circuit complexity. Although the regulator output voltage V_{OUT} is regulated, the voltage provided by the auxiliary winding that is used to power the flyback controller 132 is not regulated. When used in some power distribution applications, the output voltage V_{OUT} can vary from 3.3V to 20V. For such a wide range of output voltages, the voltage at the transformer auxiliary winding can also vary over a relatively wide range.

The relatively wide variation in the transformer auxiliary winding voltage may require use of separate low dropout (LDO) voltage regulators to power the flyback controller 132. Each of these LDO voltage regulators incrementally consume power, in addition to the power dissipated in the transformer auxiliary winding. So, eliminating the transformer auxiliary winding 138 from QR flyback converter 100 can reduce power dissipation, improve power efficiency, reduce system cost, and reduce circuit complexity in a QR flyback converter.

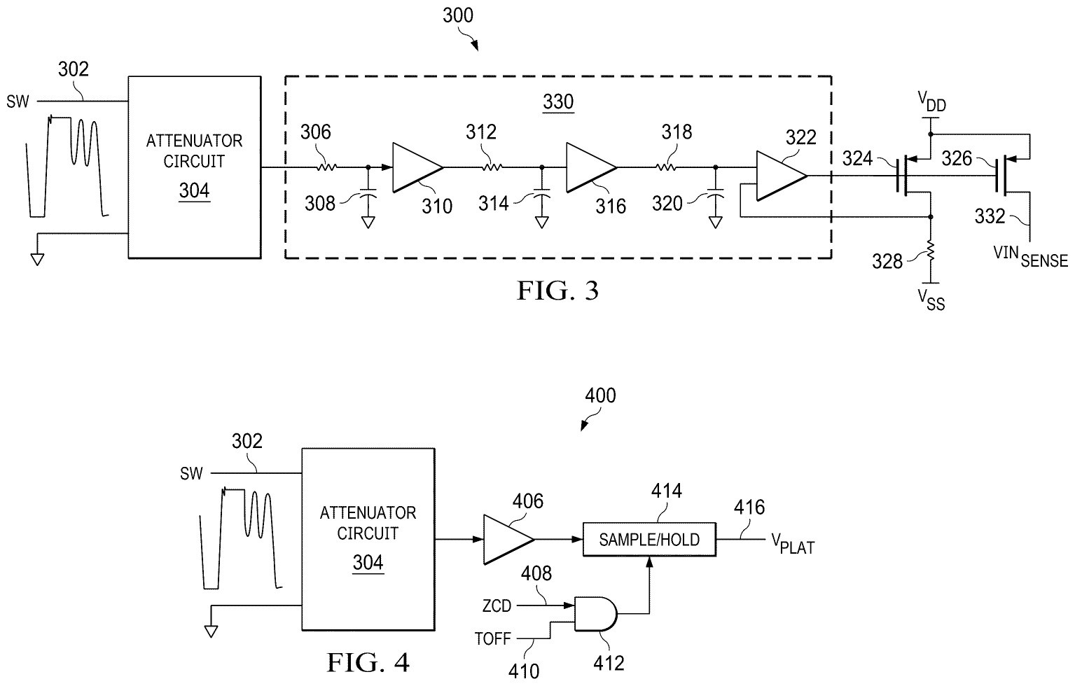

Because the transformer auxiliary winding is used to provide power to the flyback controller, sense the input voltage, and provide overpower protection, eliminating the transformer auxiliary winding requires that these functions be accomplished differently. FIG. 3 shows a schematic diagram for an example input voltage sensing circuit 300 for a QR flyback converter without the use of a transformer auxiliary winding. Input voltage sensing circuit 300 is included as part of a flyback controller circuit.

The switch terminal SW of a QR flyback converter is coupled to a first input 302 of attenuator circuit 304. A second input of attenuator circuit 304 is coupled to a ground terminal. Attenuator circuit 304 converts a voltage signal from the switch terminal SW from a high voltage domain (e.g. 400V) to a low voltage domain (e.g. 5V). This conversion helps to avoid damaging circuitry in the flyback controller circuit by exceeding the maximum voltage limit of its components. In at least one case, attenuator circuit 304 is a resistive voltage divider circuit that provides a signal at its output having a voltage division ratio (e.g. 1:200) to its input signal.

The output of attenuator circuit 304 is provided to the input of filter circuit 330. Filter circuit 330 averages the attenuated signal from the switch terminal SW. In at least one case, filter circuit 330 includes a third-order lowpass filter for averaging the attenuated signal from the switch terminal SW. Resistor 306 is coupled between the output of attenuator circuit 304 and the input of buffer amplifier 310. Capacitor 308 is coupled between the input of buffer amplifier 310 and the ground terminal. Resistor 312 is coupled between the output of buffer amplifier 310 and the input of buffer amplifier 316. Capacitor 314 is coupled between the input of buffer amplifier 316 and the ground terminal. Resistor 318 is coupled between the output of buffer amplifier 316 and a first input of amplifier 322. Capacitor 320 is coupled between the first input of amplifier 322 and the ground terminal.

Transistor 324 is coupled between a positive supply voltage terminal V_{DD}) and the second input of amplifier 322. The control terminal of transistor 324 is coupled to the output of amplifier 322. Transistor 326 is coupled between the positive supply voltage terminal V_{DD}) and an input voltage sense terminal VIN_{SENSE} 332, which is coupled to the flyback controller (not shown) and provides input voltage information to the flyback controller. Resistor 328 is coupled between the second input of amplifier 322 and a negative supply voltage terminal V_{SS}.

The input voltage is sensed by averaging the voltage of the signal from the switch terminal SW. The signal from the switch terminal SW is provided to attenuator circuit 304, which steps down the information from the high voltage domain to the low voltage domain. The information from the switch terminal SW that is stepped down to the low voltage domain is averaged using filter circuit 330. Filter circuit 330 may be, for example, a third-order lowpass filter, or could be some other type of filter. The output of filter circuit 330 is coupled to the control terminal of transistors 324 and 326.

When transistor 324 is turned on, it pumps current through resistor 328. The voltage across resistor 328 provides the power FET current information. It is important that transistor 324 be the same type of transistor as transistor 326 and be matched. This is important so that the same amount of current flows through transistor 324 as flows through transistor 326, allowing the input voltage sense information to be accurate. This circuit provides an average of the voltage at the SW node and converts that voltage into a current, which is then provided to a multiplier in the flyback controller.

The plateau voltage V_{PLAT} of the ringing voltage is equal to V_{IN}+N*V_{OUT}, and input voltage sensing circuit 300 can provide the input voltage V_{IN} information. The N*V_{OUT} information can be sensed by sampling the plateau voltage from the switch terminal SW during the off time of the power FET. FIG. 4 shows a schematic diagram for an example plateau voltage sensing circuit 400 for a QR flyback converter without the use of a transformer auxiliary winding.

The switch terminal SW of a QR flyback converter is coupled to a first input 302 of attenuator circuit 304. A second input of attenuator circuit 304 is coupled to a ground terminal. Attenuator circuit 304 converts a voltage signal from the switch terminal SW from a high voltage domain (e.g. 400V) to a low voltage domain (e.g. 5V). In at least one case, attenuator circuit 304 is a resistive voltage divider circuit that provides a signal at its output having a voltage division ratio (e.g. 1:200) to its input signal.

The output of attenuator circuit 304 is coupled to the input of buffer amplifier 406. In at least one case, buffer amplifier 406 is a unity-gain amplifier. The output of buffer amplifier 406 is coupled to the input of sample-and-hold (S/H) circuit 414. A zero-crossing detection circuit (not shown) provides as its output a signal ZCD 408 that indicates the end of the ringing on the voltage waveform at the switching terminal SW. The zero-crossing detection circuit (not shown) detects the fall in the voltage at the SW terminal, indicating that the transformer magnetizing current has been reduced to zero, which signals that the voltage at the switch terminal SW is falling from its plateau voltage.

The signal ZCD is provided as a first input to AND gate 412. A second input to AND gate 412 is a signal TOFF 410, which indicates that the power transistor is turned off. The output of AND gate 412 is coupled to the control terminal of S/H circuit 414. The output of S/H circuit 414 is coupled to circuitry in the flyback controller (not shown) and provides the signal V_{PLAT} 416, which is the plateau voltage of the ringing voltage at the switch terminal SW. The plateau voltage V_{PLAT} is equal to V_{IN}+N*V_{OUT}. The input voltage information is provided by the input voltage sense terminal VIN_{SENSE} 332 of input voltage sensing circuit 300, and the transformer turns ratio N is known in most cases for each respective system. So, the output voltage V_{OUT} can be determined.

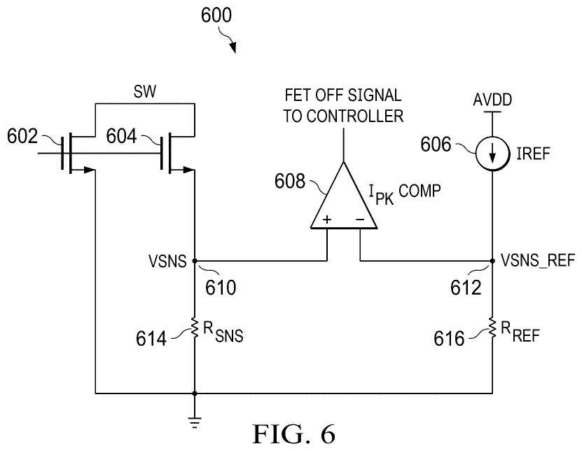

The peak current is controlled using a current sense circuit 600 as shown in FIG. 6. Transistor 602 is coupled between the switch terminal SW and the ground terminal. The control terminal of transistor 602 is coupled to a drive output of the flyback controller. Transistor 604 is coupled between the switch terminal SW and a current sense voltage terminal VSNS 610. The control terminal of transistor 604 is connected to the control terminal of transistor 602. A resistor R_{SNS} 614 is coupled between the current sense voltage terminal VSNS 610 and the ground terminal.

A reference current source IREF 506 is coupled between a voltage supply terminal AVDD and a current reference voltage terminal VSNS_REF 612, which provides a voltage proportional to the reference current. A resistor RREF 616 is coupled between the current reference voltage terminal VSNS_REF 612 and the ground terminal. A first input of comparator 608 is coupled to the current sense voltage terminal VSNS 610. A second input of comparator 608 is coupled to the current reference voltage terminal VSNS_REF 612. The output of comparator 608 is coupled to the flyback controller and provides a signal indicating that the current through transistor 602 has exceeded the reference current level, therefore, transistor 602 should be turned off.

Transistor 604 is used to sense the current flowing through transistor 602. Turning on transistor 602 also turns on transistor 604. When transistor 604 is turned on, current flows through resistor R_{SNS} 614 creating a voltage at the current sense voltage terminal VSNS 610. The voltage across resistor R_{SNS} 614 is proportional to and provides information regarding the current through transistor 602. It is important that transistor 604 be the same type of transistor as transistor 602 so that the same amount of current flows through transistor 604 as flows through transistor 602, allowing the current sense information to be accurate. In many cases, transistor 602 and transistor 604 are each a gallium nitride (GaN) FET. GaN FETs may provide better switching losses, faster response times, and lower R_{DSON} than some other types of transistors. However, other types of transistors can instead be used as long as transistor 602 and transistor 604 are each the same type.

A higher output power requirement results in a higher voltage at the current sense voltage terminal VSNS 610, although the current feedback may not be directly proportional to the output power due to offsets in the circuit. If the output power requirement is higher, the voltage regulator will be required to supply a higher peak current. This information can be provided to the FB terminal of flyback controller 132 and used by the flyback controller 132 to control the peak current. Equations (2) and (3) can be used to calculate the relationship between the voltage at the FB terminal and the peak current I_{PK}:

$${I}_{PK} = K 1 * FB\_REP \qquad ( 2 )$$

$$FB\_REP = FB - y \qquad ( 3 )$$

where K1 is a constant, FB_REP is a replica of the voltage at the FB terminal, FB is the voltage at the FB terminal of the flyback controller, and y is an offset voltage. FB is a voltage representing the output power, and is determined by sensing the current through the FET.

The input power P_{IN} is equal to (I_{PK}*V_{IN}*D)/2. So, the duty cycle D must also be determined in order to determine the input power. A first method to determine the duty cycle D is to directly sense the current from the FET and average it. A second or alternative method to determine the duty cycle D is to average FB_REP. In the first method, the signal VIN_{SENSE} is averaged. The average of VIN_{SENSE} is equal to I_{PK}*D. In the second method, FB_REP is averaged, then the average of FB_REP is divided by FB_REP to get the duty cycle D because FB_REP_{AVG}=D*FB_REP. Both the first method and the second method can provide the duty cycle D information.

In many cases, system specifications or industry standards (e.g. Limited Power Source (LPS)) may require that the output current and power be limited during operation under all conditions. For a lower voltage at the output voltage terminal V_{OUT} 170, the output current may need to be limited. For a higher voltage at the output voltage terminal V_{OUT} 170, overpower protection may be required. Output current limiting can be provided by indirectly sensing the output current. The input voltage V_{IN}, the output voltage V_{OUT}, and the peak current I_{PK} can be determined. The output power, P_{OUT}, is equal to V_{OUT}*I_{OUT}, which is equal to I_{PK}*V_{IN}*D. The value of I_{PK}*D can be sensed, and together with the output voltage information and a different multiplier, can provide both overpower protection and output current limiting.

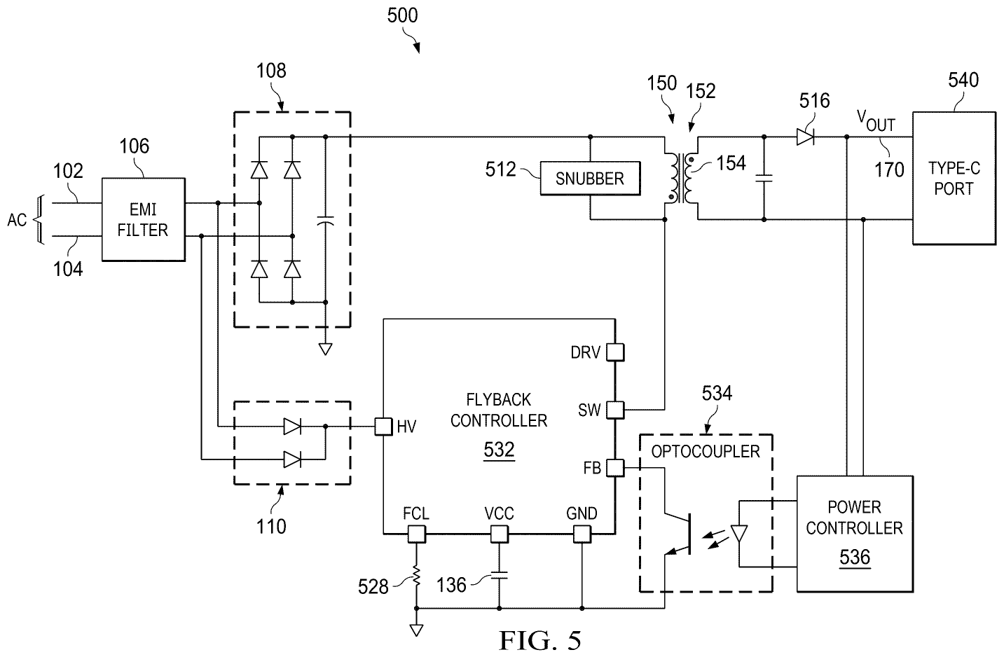

FIG. 5 shows a schematic diagram for an example QR flyback converter 500 without the use of a transformer auxiliary winding. QR flyback converter 500 receives an AC power input at input terminals 102 and 104. An EMI filter 106 has an input coupled to input terminals 102 and 104, and has an output. The output of EMI filter 106 is coupled to the input of full-wave rectifier circuit 108. Startup protection circuit 110 is coupled between the output of EMI filter 106 and a ground terminal.

Transformer 154 has a primary 150 and a secondary 152. The first output of full-wave rectifier circuit 108 is coupled to a first terminal of the transformer primary 150. Snubber circuit 512 is coupled between the first terminal of the transformer primary 150 and a second terminal of the transformer primary 150. In at least one case, snubber circuit 512 includes a resistor and a capacitor coupled in parallel.

The secondary 152 of transformer 154 has first and second terminals. Diode 516 has an anode coupled to the first terminal of the transformer secondary 152. A cathode of diode 516 is coupled to the output voltage terminal V_{OUT} 170. Power controller 536 has a first input coupled to the output voltage terminal V_{OUT} 170, and a second input coupled to the second terminal of the transformer secondary 152.

Flyback controller circuit 532 has a frequency clamp terminal FCL, a feedback terminal FB, a switch terminal SW, a transistor drive terminal DRV, a GND terminal that is coupled to the ground terminal, a supply terminal VCC, and a high voltage startup terminal HV. The high voltage startup terminal HV is coupled to the output of startup protection circuit 110. The supply terminal VCC is coupled to ground through capacitor 136. The frequency clamp terminal is coupled to ground through resistor 528.

Optocoupler 534 has first and second inputs that are coupled to first and second outputs of power controller 536. Optocoupler 534 has a first output coupled to the feedback terminal FB, and a second outputs that is coupled to ground. Optocoupler 534 provides DC isolation between the power controller 536 and the flyback controller circuit 532. A type-C port is coupled between the output voltage terminal VOUT 170 and the second terminal of the transformer secondary 152.

Flyback controller circuit 532 includes input voltage sensing circuit 300 and plateau voltage sensing circuit 400 and has an integrated E-mode GaN FET. QR flyback converter 500 is able to provide output power protection and helps to support power standard requirements, such as limited power source (LPS), all without the need for an auxiliary transformer winding. Elimination of the auxiliary transformer winding can simplify the QR flyback converter design while reducing the overall system cost.

In this description, “terminal,” “node,” “interconnection,” “lead” and “pin” are used interchangeably. Unless specifically stated to the contrary, these terms generally mean an interconnection between or a terminus of a device element, a circuit element, an integrated circuit, a device, or other electronics or semiconductor component.

In this description, “ground” includes a chassis ground, an Earth ground, a floating ground, a virtual ground, a digital ground, a common ground and/or any other form of ground connection applicable to, or suitable for, the teachings of this description.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, so device B is controlled by device A via the control signal generated by device A.

In this description, even if operations are described in a particular order, some operations may be optional, and the operations are not necessarily required to be performed in that particular order to achieve specified results. In some examples, multitasking and parallel processing may be advantageous. Moreover, a separation of various system components in the embodiments described above does not necessarily require such separation in all embodiments.

Modifications are possible in the described embodiments, and other embodiments are possible, within the scope of the claims.

1. A protection circuit, comprising:
a voltage attenuator circuit having an attenuator input and an attenuator output, wherein the attenuator input is coupled to a switch terminal;
a filter circuit having a filter input and a filter output, wherein the filter input is coupled to the attenuator output;
a first transistor having first and second current terminals and a first control terminal, wherein the first current terminal is coupled to a power supply terminal, and the first control terminal is coupled to the filter output;
a second transistor having third and fourth current terminals and a second control terminal, wherein the third current terminal is coupled to the first current terminal, the second control terminal is coupled to the first control terminal, the fourth current terminal is coupled to a first voltage sense terminal;
a resistor coupled between the second current terminal and a reference voltage terminal;
a buffer circuit having a buffer input and a buffer output, wherein the buffer input is coupled to the attenuator output; and
a sample-and-hold (S/H) circuit having a sample input, a sample control terminal and a sample output, wherein the sample input is coupled to the buffer output, the sample output is coupled to a second voltage sense terminal, and the S/H circuit is configured to provide at the sample output a minimum ringing voltage of a signal from the switch terminal.

2. The protection circuit of claim 1, wherein the filter circuit is a lowpass filter and provides a signal at the filter output that is an average of a signal at the filter input.

3. The protection circuit of claim 2, wherein the lowpass filter is a third order lowpass filter.

4. The protection circuit of claim 1, wherein the first transistor and the second transistor are matched.

5. The protection circuit of claim 3, wherein the resistor is a first resistor, and the filter circuit includes:
a first amplifier having a first amplifier input and a first amplifier output;
a second resistor coupled between the attenuator output and the first amplifier input;
a first capacitor coupled between the first amplifier input and a ground terminal;
a second amplifier having a second amplifier input and a second amplifier output;
a third resistor coupled between the first amplifier output and the second amplifier input;
a second capacitor coupled between the second amplifier input and the ground terminal;
a third amplifier having third and fourth amplifier inputs and a third amplifier output, wherein the third amplifier output is coupled to the first control terminal, and the fourth amplifier input it coupled to the second current terminal;
a fourth resistor coupled between the second amplifier output and the third amplifier input; and
a third capacitor coupled between the third amplifier input and the ground terminal.

6. The protection circuit of claim 1, further comprising a logic circuit having first and second logic inputs and a logic output, wherein the logic output is coupled to the sample control terminal, and the logic circuit is configured to cause the S/H circuit to sample an input signal at the sample input at a time when the input signal is at a minimum voltage and the first transistor is turned off.

7. The protection circuit of claim 6, wherein the logic circuit is an AND gate, the first logic input is coupled to an output of a zero crossing detection circuit, and the second logic input is coupled to a circuit providing a signal indicating that the first transistor is turned off.

8. The protection circuit of claim 1, wherein the minimum ringing voltage is equal to a sum of an input voltage and a product of an output voltage and a transformer turns ratio.

9. The protection circuit of claim 1, wherein the first voltage sense terminal provides a voltage that is proportional to an input voltage.

10. The protection circuit of claim 1, wherein the voltage attenuator circuit includes a resistive voltage divider circuit.

11. A system, comprising:
a rectifier circuit having a rectifier input and a rectifier output, wherein the rectifier input is coupled to an AC power input;
a transformer having a transformer primary and a transformer secondary, wherein the transformer primary is coupled to the rectifier output, and the transformer secondary is coupled to an output voltage terminal;
a voltage attenuator circuit having an attenuator input and an attenuator output, wherein the attenuator input is coupled to a switch terminal;
a filter circuit having a filter input and a filter output, wherein the filter input is coupled to the attenuator output;
a first transistor having first and second current terminals and a first control terminal, wherein the first current terminal is coupled to a power supply terminal, and the first control terminal is coupled to the filter output;
a second transistor having third and fourth current terminals and a second control terminal, wherein the third current terminal is coupled to the first current terminal, the second control terminal is coupled to the first control terminal, the fourth current terminal is coupled to a first voltage sense terminal, and the second transistor is matched to the first transistor;
a resistor coupled between the second current terminal and a reference voltage terminal;
a buffer circuit having a buffer input and a buffer output, wherein the buffer input is coupled to the attenuator output; and
a sample-and-hold (S/H) circuit having a sample input, a sample control terminal and a sample output, wherein the sample input is coupled to the buffer output, the sample output is coupled to a second voltage sense terminal, and the S/H circuit is configured to provide at the sample output a minimum ringing voltage of a signal from the switch terminal.

12. The system of claim 11, wherein the filter circuit is a lowpass filter and provides a signal at the filter output that is an average of a signal at the filter input.

13. The system of claim 12, wherein the lowpass filter is a third order lowpass filter.

14. The system of claim 11, wherein the first transistor and the second transistor are matched.

15. The system of claim 13, wherein the resistor is a first resistor, and the filter circuit includes:
a first amplifier having a first amplifier input and a first amplifier output;
a second resistor coupled between the attenuator output and the first amplifier input;
a first capacitor coupled between the first amplifier input and a ground terminal;
a second amplifier having a second amplifier input and a second amplifier output;
a third resistor coupled between the first amplifier output and the second amplifier input;
a second capacitor coupled between the second amplifier input and the ground terminal;
a third amplifier having third and fourth amplifier inputs and a third amplifier output, wherein the third amplifier output is coupled to the first control terminal, and the fourth amplifier input it coupled to the second current terminal;
a fourth resistor coupled between the second amplifier output and the third amplifier input; and
a third capacitor coupled between the third amplifier input and the ground terminal.

16. The system of claim 11, further comprising a logic circuit having first and second logic inputs and a logic output, wherein the logic output is coupled to the sample control terminal, and the logic circuit is configured to cause the S/H circuit to sample an input signal at the sample input at a time when the input signal is at a minimum voltage and the first transistor is turned off.

17. The system of claim 16, wherein the logic circuit is an AND gate, the first logic input is coupled to an output of a zero crossing detection circuit, and the second logic input is coupled to a circuit providing a signal indicating that the first transistor is turned off.

18. The system of claim 11, wherein the minimum ringing voltage is equal to a sum of an input voltage and a product of an output voltage and a transformer turns ratio.

19. The system of claim 11, wherein the first voltage sense terminal provides a voltage that is proportional to an input voltage.

20. The system of claim 11, wherein the voltage attenuator circuit includes a resistive voltage divider circuit.
